(19) United States
(12) Patent Application Publication
(10) Pub. No.: US 2025/0148144 A1
(43) Pub. Date: May 8, 2025

(54) SYSTEMS AND METHODS FOR MULTI-STAGE FOUNDATION AND DYNAMIC STRUCTURE CONSTRUCTION

(71) Applicant: SENTERPRISYS LIMITED, ROCKLEA (AU)

(72) Inventor: Lev Mizikovsky, Woody Point (AU)

(21) Appl. No.: 18/940,120

(22) Filed: Nov. 7, 2024

Related U.S. Application Data
(60) Provisional application No. 63/596,726, filed on Nov. 7, 2023.

(51) Int. Cl. G06F 30/13; E02D 15/02

(52) U.S. Cl. CPC G06F 30/13; E02D 15/02

(57) ABSTRACT

A system includes a processor, an input device, an output device, a memory, and programming in the memory. Execution of the programming by the processor configures the system to perform the following functions. The system receives a foundation file, an initial structure file, and an alternative structure file. The system determines an initial congruency between the foundation file and the initial structure file based on respective boundaries and opening points, and an alternative congruency between the foundation file and the alternative structure file based on respective boundaries and opening points. Based upon the alternative congruency equaling or exceeding the initial congruency, the system outputs a valid pairing between the foundation file and the alternative structure file.

### CROSS-REFERENCE TO RELATED APPLICATIONS

This application claims priority to U.S. Provisional Application No. 63/596,726, filed Nov. 7, 2023, entitled “BUILDING METHOD”, the entire contents of which are incorporated herein by reference.

### TECHNICAL FIELD

The present disclosure relates to orderly design and construction of building foundations and structures, and the alignment during multi-stage planning and approval of multiple potential structure designs to one or more foundation designs.

### BACKGROUND

Conventionally, tract housing and certain spec housing construction by land developers involves a rigid, multi-step process. First, land is obtained by the land developer, upon which one or more houses are intended to be constructed for sale to buyers. Next, the land developer develops a site plan, which often describes where any buildings, roads, and utilities will be allocated throughout the site, and also in the case of tract housing divides the site up into parcels. Next, the housing upon each individual parcel is designed by a structural engineer. Throughout this process, local government and zoning committees are consulted, which ultimately approve the larger site plan, as well as the smaller parcel plans. The parcel plans include both a plan for the foundation of the building, as well as a plan for the structure which will sit upon the foundation. Once the larger site plan is approved, and some or all of the parcel plans are approved, the land developer is able to break ground and begin construction, building upon the parcels both the foundation and the structure.

Often, the land developer will not construct identical structures on each parcel on the site. Structures will have aesthetic variations, both external and internal, in order to provide variety throughout the completed community. The land developers will also vary the features and layouts of structures, in order to target a variety of tastes and price points. For example, some parcels will include town homes, while some will include single family homes. Some will include multi-story construction, while others will be single-story, ranch-style homes. Some structures may include an attached garage, while some may use that space as a storage area, a secondary suite, or an expanded kitchen and dining area. Some structures may include an additional bedroom on a second floor, while others will include a multi-story foyer. Certain structures may need to include an elevator for disabled homeowners, the space for which would otherwise be large closets, additional bathrooms, or dens.

Conventionally, land developers will need to guess or estimate the needs of the future purchasing community at the time of plan proposal and approval, even though construction may not be completed for months or years. These land developers need to make these selections early, even though generally variations within the approved structures are acceptable or tolerated by local government and zoning committees after construction commences, so long as the variations conform to the local code and zoning regulations.

Variations in construction can be expected when constructing something as complex as a house or building, which requires a group of disparate, multidisciplinary contractors to work together in a coordinated fashion to complete construction. Some variations, however, may be made by parties which purchase structures which are still under construction. These parties may request that, for example, certain non-load-bearing walls be moved or removed, additional windows be installed, external brick facades be used instead of vinyl siding, or certain appliances (which may vary in size and load requirements as compared to the planned appliances) be installed. So long as the developer is able to legally and cost-effectively accommodate these variations, they often will endeavor to do so in order to better satisfy purchasers.

However, these intentional variations can be difficult in many instances to implement: stairs may be installed, window and door headers may be built in, and water, electric, gas, and heating, ventilation, and air conditioning (HVAC) runs and openings may already be installed.

Therefore, there is a long-felt but unsolved need for systems and methods of constructing structures whereby construction can be planned and approved by appropriate regulatory authorities, but variations and customizations can be readily and cost-effectively implemented for the ultimate purchaser of structure on a land developer's site.

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

A system for dynamic alignment of a structure plan with a foundation plan may include a processor, an input device coupled to the processor, an output device coupled to the processor, a memory coupled to the processor, and programming in the memory, wherein execution of the programming by the processor configures the system to perform the following functions. The system receives at the input device a foundation input file. The foundation input file includes a foundation boundary vector space comprising one or more foundation boundary vectors, the one or more foundation boundary vectors forming a foundation perimeter. The foundation input file also includes one or more foundation opening points, the one or more foundation opening points defined within or upon the foundation perimeter. The system receives an initial structure input file. The initial structure input file includes an initial structure boundary vector space comprising one or more initial structure boundary vectors, the one or more initial structure boundary vectors forming an initial structure perimeter. The initial structure input file also includes one or more initial structure opening points, the one or more initial structure opening points defined within or upon the initial structure perimeter. The system determines an initial perimeter congruency value between the foundation perimeter and the initial structure perimeter. The system determines an initial opening overlap value where each initial structure opening point overlaps an initial respective foundation opening point of the foundation opening points. The system receives a plurality of alternative structure input files. Each alternative structure input file of the alternative structure input files includes an alternative structure boundary vector space comprising one or more alternative structure boundary vectors, the one or more alternative structure boundary vectors forming an initial structure perimeter. Each alternative structure input file also includes one or more alternative structure opening points, the one or more alternative structure opening points defined within or upon the alternative structure perimeter. For a respective alternative structure input file, the system determines an alternative perimeter congruency value between the foundation perimeter and a respective alternative structure perimeter of the respective alternative structure input file. The system determines an alternative opening overlap value where each alternative structure opening point overlaps an alternative respective foundation opening point of the foundation opening points. The system determines the alternative perimeter congruency value is within a congruency tolerance range of the initial perimeter congruency value, and the alternative opening overlap value is within an overlap tolerance range of the initial opening overlap value. The system outputs a valid pairing including the foundation input file and the respective alternative structure input file.

Alternatively, in some embodiments the perimeter congruency value and the opening overlap value is determined based solely on the foundation input file, as opposed to utilizing both the initial structure input file and the foundation input file. This alternative may be used if the final purchaser is comfortable with a structure that is smaller or less congruent than the structure described within the initial structure input file, which nevertheless fits within the foundation perimeter and has openings which each align with a respective foundation opening point.

In some embodiments, the one or more foundation opening points correspond to drainage openings.

In some embodiments, one or more edge foundation opening points of the one or more foundation opening points corresponds to an external line.

In a subset of those embodiments, each foundation opening point of the one or more foundation opening points is a particular edge foundation opening point of the edge foundation opening points, or is an internal foundation opening point connected to a respective edge foundation opening point of the edge foundation opening points.

In a subset of those embodiments, a connection between a respective internal foundation opening point and the respective edge foundation opening point corresponds to a dedicated connection.

In a different or overlapping subset of those embodiments, a connection between a respective internal foundation opening point and the respective edge foundation opening point corresponds to a general raceway or sleeve.

In some embodiments, the one or more foundation opening points include correspondences to drainage openings, cold water openings, hot water openings, gas line openings, electrical line openings, or a combination thereof.

In some embodiments, the system further includes a regulatory database, and the respective alternative structure input file conforms to each relevant regulation M in the regulatory database.

In some embodiments, the foundation input file corresponds to a constructed foundation, and the respective alternative structure file corresponds to a constructed structure.

In a subset of those embodiments, the foundation opening points includes one or more unused opening points and one or more used opening points. A respective unused opening point corresponds to a physical opening in the constructed foundation configured to be closed. A respective used opening point corresponds to a physical connection between a fixture and an external line via the respective used opening point.

In a different or overlapping subset of those embodiments, the constructed foundation is a slab or a basement, and the constructed structure in a housing unit.

In some embodiments, an initial structure opening point of the initial structure input file corresponds to a fixture of a first type (e.g., a shower), and an alternative structure opening point of an alternative structure input file corresponds to a fixture of a second type (e.g., a bathtub, or anything other than the shower or fixture of the first type.)

In some embodiments, execution of the programming by the processor further configures the system to perform the following functions. The system outputs a preliminary pairing including the foundation input file and the initial structure input file. The system receives selection input selecting or ranking one or more of the plurality of alternative structure input files. The system outputs a preferred pairing including the foundation input file and a preferred alternative structure input file, the preferred structure input file being a most preferred alternative structure input file among the selection input associated with a preferred congruency value within the congruency tolerance range of the initial perimeter congruency value, the preferred opening overlap value within the overlap tolerance range of the initial opening overlap value.

In some embodiments, one or more alternative structure input files of the plurality of alternative structure input files are generated by a machine learning or artificial intelligence module trained on one or more sample pairings of a sample foundation input file and a sample initial structure input file.

In some embodiments, the system further includes automated concrete pourer, and execution of the programming by the processor further configures the system to perform the following functions. The system, utilizing the automated concrete pourer, fabricates a constructed foundation based upon the one or more foundation boundary vectors and the one or more foundation opening points of the foundation input file.

A method may include constructing a constructed foundation in accordance with an initial architectural plan on a plot of land. The method may include selecting an alternative architectural plan from a plurality of alternative architectural plans, each alternative architectural plan of the plurality of alternative architectural plans compatible for construction upon the constructed foundation.

In some embodiments of the method, the constructed foundation may include predetermined drainage points configured to accommodate an initial plumbing configuration of the initial architecture plan and one or more alternative plumbing configurations of one or more alternative architecture plans of the plurality of alternative architectural plans.

In a subset of those embodiments of the method, an initial boundary of the initial architecture plan is congruent with an alternative boundary of the alternative architectural plan. The initial plumbing configuration aligns with the alternative plumbing configuration.

In some embodiments of the method, the method further includes selecting the initial architectural plan based on suitability for the plot of land. The method includes obtaining regulatory approval for the constructed foundation on the basis of the initial architectural plan in. The method includes constructing an alternative residential structure according to the alternative architectural plan, upon the constructed foundation.

A building foundation may include a foundation perimeter and one or more foundation opening points, the one or more foundation opening points defined within or upon the foundation perimeter. The building foundation is configured to allow the affixment of an initial structure including one or more initial fixtures. The one or more foundation opening points are configured to align with one or more initial appliances affixed within the initial structure. The building foundation is configured to allow the affixment of an alternative structure including one or more alternative fixtures. The one or more foundation opening points are configured to align with one or more alternative appliances affixed within the alternative structure.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings.

FIG. 1 is a block diagram of a plan alignment module and data values for dynamic pairing of a structure plan with a foundation plan.

FIG. 2A is a simplified foundation plan for a foundation, in particular indicating sewer outflows and external lines.

FIG. 2B is the simplified foundation plan of FIG. 2A, in particular indicating cold water inflows and external lines.

FIG. 2C is the simplified foundation plan of FIG. 2A, in particular indicating hot water inflows and outflows.

FIG. 2D is the simplified foundation plan of FIG. 2A, in particular indicating electrical panels and external lines.

FIG. 2E is the simplified foundation plan of FIG. 2A, in particular indicating gas outflows and external lines.

FIG. 3A is a first structural plan for a first structure affixable to the foundation of the foundation plan.

FIG. 3B is a second structural plan for a second structure affixable to the foundation of the foundation plan.

FIG. 3C is a third structural plan for a third structure affixable to the foundation of the foundation plan.

FIG. 4 is a simplified foundation plan for a multi-line foundation, in particular indicating an additional set outflows and alternative external lines.

FIG. 5 is a flowchart depicting the dynamic structure plan foundation plan protocol.

FIG. 6 is a block diagram of one example of an architecture of a computing device that may be used in a system to implement a protocol, in accordance with some embodiments.

In the drawings, reference numbers may be reused to identify similar and/or identical elements.

### DETAILED DESCRIPTION

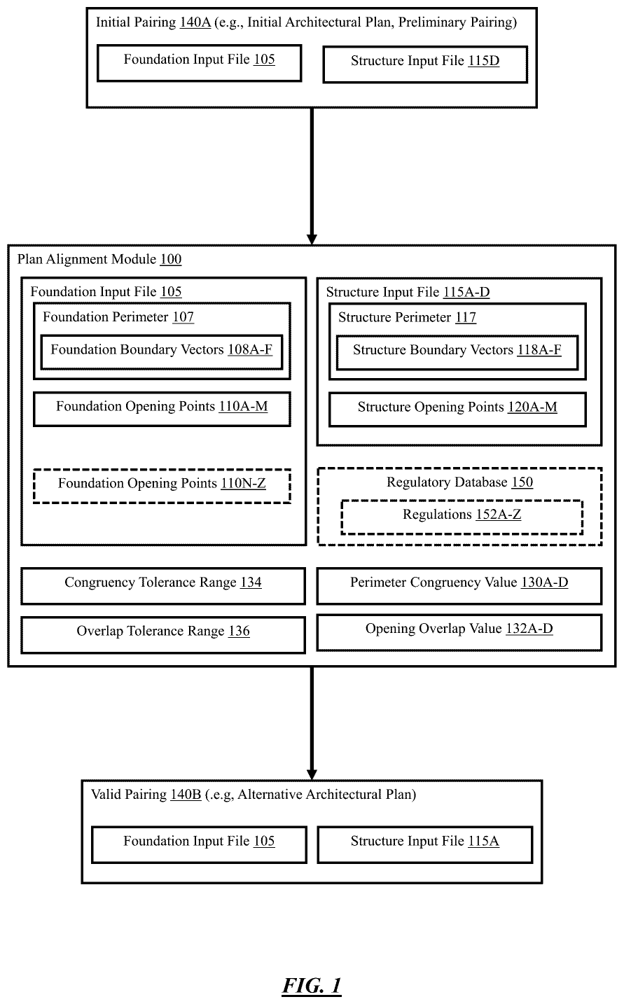

FIG. 1 is a block diagram of one example of a plan alignment module 100 and data values for dynamic pairing of a structure plan with a foundation plan in accordance with some embodiments. The plan alignment module 100 is a software module configured to receive a preliminary pairing of a construction plan describing a foundation and a construction plan describing a structure which fits with the described foundation, and produces an alternative construction plan describing an alternative structure which fits with the described foundation, but has one or more wall, fixtures, or features changed or moved as compared to the initial structure. The plan alignment module 100 may be instructions, code, or a program or process executable or executed upon an appropriate computing device as described herein.

In some embodiments, a foundation can include a slab, a basement, support stumps, or a crawlspace. However, any sort of construction or site preparation which facilitates securing a structure to the parcel for which it is intended may be a foundation: for example, a foundation can include driven pilings into sandy site, can include a rock blasting outcome, a leveled earthen area, embankments, redirected water, or could include fixture brackets driven into rock or ice. A construction plan may describe the process of producing the foundation, and can include traditional blueprints, or any format of human- or machine-readable material describing one or more facets or features, including perimeters, of the foundation produced.

In some embodiments, a structure can include a single family home, or any structure compatible with a foundation conforming to the foundation plan, including multi-family units, townhomes, individual condominium units of condominium facility, office buildings, individual floors of an office building, storage facilities, garages, hangars, warehouses, factories, individual sections of factories, and any super- or sub-division thereof. A structure can include a single story, or multiple stories. For the purposes of this disclosure, each floor of a structure can be treated like a foundation, such as in flat plate construction for multistory construction. Alternatively, a floor may be treated as essentially porous with respect to fixtures, appliances, or openings passing from a lower level through an upper floor.

In some embodiments, the plan alignment module may receive the foundation plan as a foundation input file 105, and the structure plan as a structure input file 115D. The foundation input file 105 can be received individually, or as a pairing 140A with the structure input file 115D.

In some embodiments, the foundation input file 105 includes a foundation perimeter 107. The foundation perimeter 107 defines the perimeter or boundary of the foundation to be constructed: generally, any structure to be constructed on the foundation would need to be constructed within the foundation perimeter 107, and the foundation perimeter 107 is to be filled with constructed structure. The foundation perimeter 107 may include only the area and constructed foundation which is required to support a traditional structure such as a house or occupied building. Generally, the foundation perimeter 107 describes an area with uniform strength, such that interior walls, floors, fixtures, and appliances could be placed anywhere within the foundation perimeter 107 without causing undue stress to the foundation.

In some embodiments, concrete patios and garage slabs may be poured at the same time as the traditional structure foundation, and may be included in the foundation perimeter 107, particularly if utilities travel through or under the slabs. However, concrete patio and garage slabs may be poured thinner than traditional structure slabs, may not involve utilities, and may not be controlled under local regulatory organizations-therefore, these supporting constructions which are considered foundations may not be defined within the foundation perimeter 107.

In some embodiments, certain structure elements of the structure may be outside the foundation perimeter 107, such as air conditioning units, overhangs, protruding windows, driveways, detached garages, etc. generally because that structure element floats over the ground, or sits on some type of secondary, inferior, unregulated, or later-constructed foundation. Likewise, certain areas of the foundation perimeter 107 may not have any structure constructed above, such as a patio or a concrete porch or steps.

In some embodiments, the foundation perimeter 107 is described by one or more foundation boundary vectors 108A-F. The foundation boundary vectors 108A-F are defined such that there is no gap in the foundation perimeter 107. Foundation boundary vectors 108A-F facilitate comparing the foundation perimeter 107 to other perimeters to be described later.

In some embodiments, the foundation input file 105 includes one or more foundation opening points 110A-M. In general, foundation opening points 110A-M describe a location at which one or more passages through the foundation appear on the surface of the foundation. Foundation opening points 110A-M can include where public utilities enter the property through the foundation. Foundation opening points 110A-M can include where openings for drainage, water lines, electrical lines, and gas are able to ingress into the structure, having entered from the edge of the property. For example, a foundation opening point 110A may describe a drainage opening in the center of the foundation perimeter 107, and foundation opening 110B may describe a drainage opening on the edge of the foundation perimeter 107, connected through or under the foundation, which allows liquid to flow from foundation opening point 110A to foundation opening 110B. Consequently, the structure may include a drain at or near foundation opening point 110A: fluids entering such a drain would be able to flow to foundation opening 110B and out to a public sewer or septic tank.

In some embodiments, foundation opening points 110A-M describe openings for drainage (e.g., sewage), hot water, cold water, gas, electric, forced air, or any other type of utility or flowed resource. A single opening point 110A may correlate to multiple nearby openings, e.g., a ¾ inch hot water line six inches from a ¾ inch cold water line, six inches from a drainage line. In such examples, that single opening point 110A may connected to different opening points 110B-D based on the type of line traversing the opening points 110A-D, e.g., a drainage line may run from opening point 110A to opening point 110B, a hot water line may run from opening point 110A to opening point 110C, and a cold water line may run from opening point 110A to opening point 110D, while no drainage line runs from opening point 110B to opening point 110C or from opening point 110B to opening point 110D. Alternatively, two or more opening points 110A-B may be connected by a raceway, allowing various lines to be run between the two or more opening points 110A-B as needed after the foundation is constructed.

In some embodiments, the structure input file 115D may be an initial structure input file 115D, which is known or ascertained to conform to the foundation input file 105. The plan alignment module 100 can include multiple structure input files 115A-D, some of which may or may not conform to the foundation input file 105. The initial structure input file 115D includes a structure perimeter 117 which is generally congruent to the foundation perimeter 107, and includes structure boundary vectors 118A-F defining the structure perimeter 117 and each pairing generally with a foundation boundary vector 108A-F. The initial structure input file 115D also includes structure opening points 120A-M. Each structure opening point 120A-M corresponds to one or more features, fixtures, or appliances in the to-be-completed structure. For example, structure opening point 120A may correspond to a bathtub, a sink, or a shower. Structure opening points 120A-M include any features, fixtures, or appliances which requires a line or resource to be connected to the feature, fixture, or appliance via an opening in the foundation. Structure opening points 120A-M can include elements which are not traditionally considered a feature, fixture, or appliance, such as a high-voltage run, an opening for a sump pump, well water, or geothermal heat pump, or a pylon for supporting higher floors-any element which passes through the foundation or requires a resource passed through the foundation may require a structure opening point 120A-M.

In some embodiments, other structure input files 115A-C include similar elements as the initial structure input file 115D, but can include other values e.g., different structure perimeters 117 or placements of structure opening points 120A-M.

In some embodiments, the plan alignment module 100 determines conformance between a structure input file 115A-D and a foundation input file 105 in a multi-step process. The plan alignment module 100 determines whether the foundation perimeter 107 is generally congruent with the structure perimeter 117 of a given structure input file 115A. Determining congruency is facilitated by comparing the foundation boundary vectors 108A-F to the structure boundary vectors 118A-F of the structure input file 115A. Some variance can be acceptable—for example, so long as the structure perimeter 117 fits within the foundation perimeter 107, it is acceptable; or, so long as the structure perimeter 117 does not deviate from the foundation perimeter 107 by more than one inch or 1% along any pair of vectors 108A, 118A, it is acceptable. The acceptability of variance is described in the congruency tolerance range 134. The foundation perimeter 107 is compared to the structure perimeter 117, producing a perimeter congruency value 130A, and if the perimeter congruency value 130A is within the congruency tolerance range 134, the two perimeters 107, 117 are treated as congruent and conforming.

In some embodiments, the plan alignment module 100 also determines whether the structure opening points 120A-M overlap appropriate foundation opening points 110A-M. Again, some variance can be acceptable, and that acceptability of variance is described in the overlap tolerance range 136. The structure opening points 120A-M are overlaid on the foundation opening points 110A-M, producing an opening overlap value 132A, and if the opening overlap value value 132A is within the overlap tolerance range 133, the structure opening points 120A-M are treated as correctly overlapping the foundation opening points 110A-M and conforming.

Structure opening points 120A-M may only be compared to foundation opening points 110A-M of the same time or facilitating the same type of connections. For example, if structure opening point 120A overlaps foundation opening point 110A, but structure opening point 120A requires an electrical run and foundation opening point 110A facilitates a cold water run, then for the purposes of the overlap tolerance range 136 structure opening point 120A does not overlaps foundation opening point 110A. A broader purpose foundation opening point 110B may facilitate a narrower-purpose structure opening point 110B, but not necessarily vice versa: meaning, a general raceway 110B in the foundation can provide hot water to a dishwasher at opening point 120B, but a hot water run 110C cannot provide gas to an HVAC heater at opening point 120C.

Relatedly, in some embodiments the structure opening points 120A-M overlap appropriate foundation opening points 110A-M, but foundation opening points 110A-M do not necessarily overlap structure opening points 120A-M. returning to the foundation input file 105, in some embodiments, the foundation input file 105 may include foundation opening points 110N-Z, which have no relevance to structure input file 115D. However, one or more foundation opening points 110N-Z may be overlapped by structure opening points 120A-M in another structure input file 15B. Foundation opening points 110N-Z may interconnect with one or more foundation opening points 110A-M, or foundation opening points 110N-Z may be separate from the one or more foundation opening points 110A-M.

In some embodiments, conformance checking may also include a regulatory check. Plan alignment module 100 can include a regulatory database 150 of regulations 152A-Z. In checking conformance between the foundation input file 105 and the structure input file 115A-D, plan alignment module 100 determines which regulations 152A-M apply to the location of construction, as well as to the type of building to be constructed. Then, plan alignment module 100 determines whether the structure described in structure input file 115A-D affixed to the foundation described in foundation input file 105 would conform to the regulations 152A-M. For example, in some jurisdictions, raceways cannot include both water and electric lines; while others allow a sleeved electrical line in the same raceway as water lines; some jurisdictions define how close a toilet must be to a wall, while others have no such requirement. If a structure input file 115A-D, either alone or in its relationship to the foundation input file 105 does not conform to the regulations 152A-M, then the two files are not conforming.

In some embodiments, if a foundation input file 105 and a structure input file 115A conform with respect to congruency of perimeter and overlapping of openings, and conform to relevant regulations 152A-M, the plan alignment module 100 determines the two files form a valid pairing 140B. The valid pairing 140B includes the foundation input file 105 and a conforming structure input file 115A. The initial pairing 140A may be presumed to be a valid pairing, or the plan alignment module 100 may determine conformance independently. The plan alignment module may also use a perimeter congruency value 130D and an opening overlap value 132D as the bases for the congruency tolerance range 134 and the overlap tolerance range 136: for example, if the initial structure input file 115D is three inches shorter on a southern face than the foundation input file 105, then a three inch discrepancy on the southern face of the structure input files 115A-C as compared to the foundation input file 105 may be tolerable.

The valid pairing 140B is then exported as an alternative option for a land developer: rather than constructing the structure based on the initial structure input file 115D affixed to a foundation based on the foundation input file 105, the developer may instead construct a structure based on the alternative structure input file 115A affixed to the foundation.

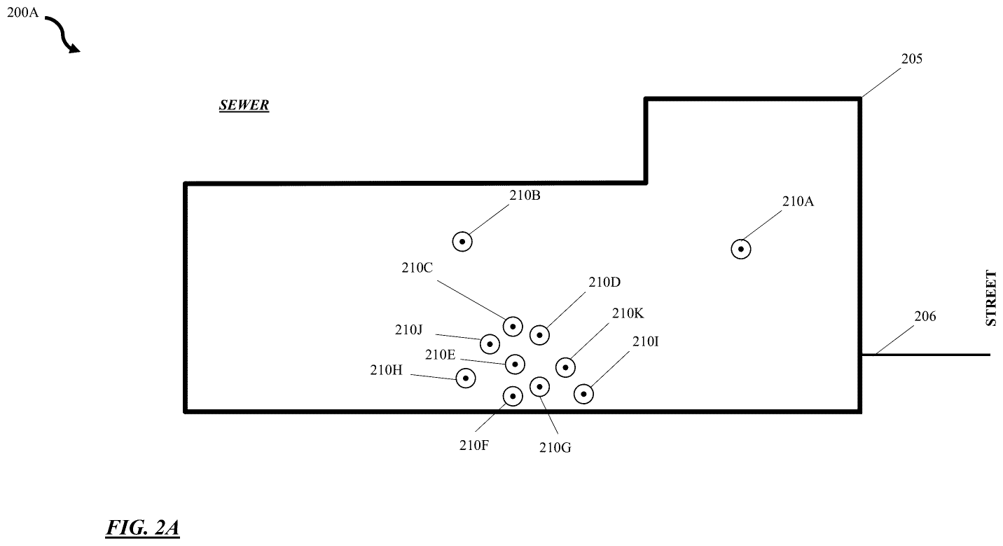

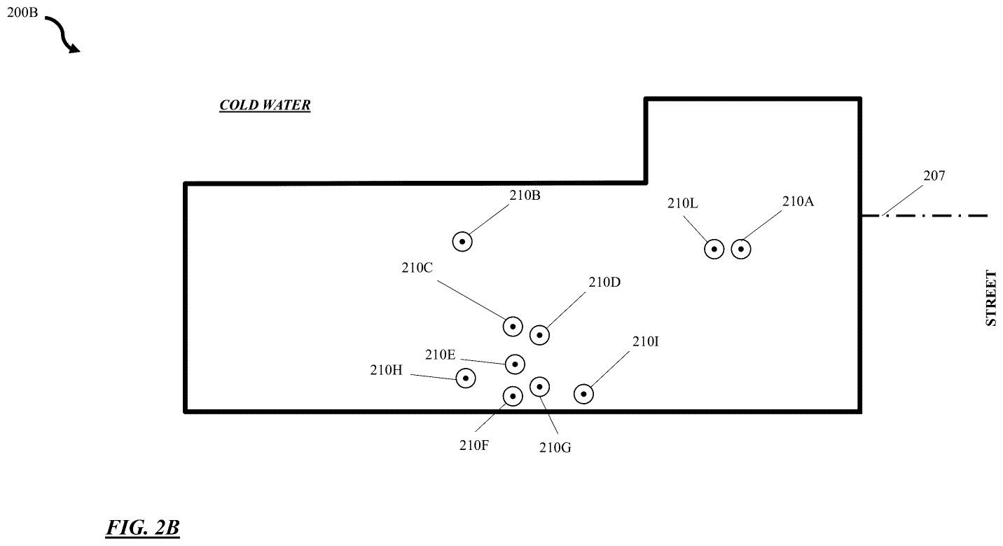

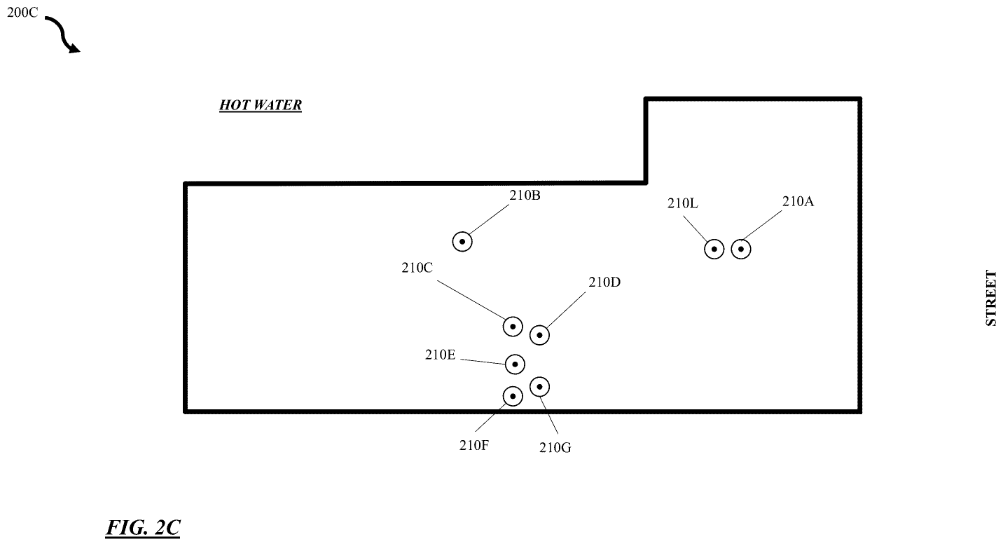

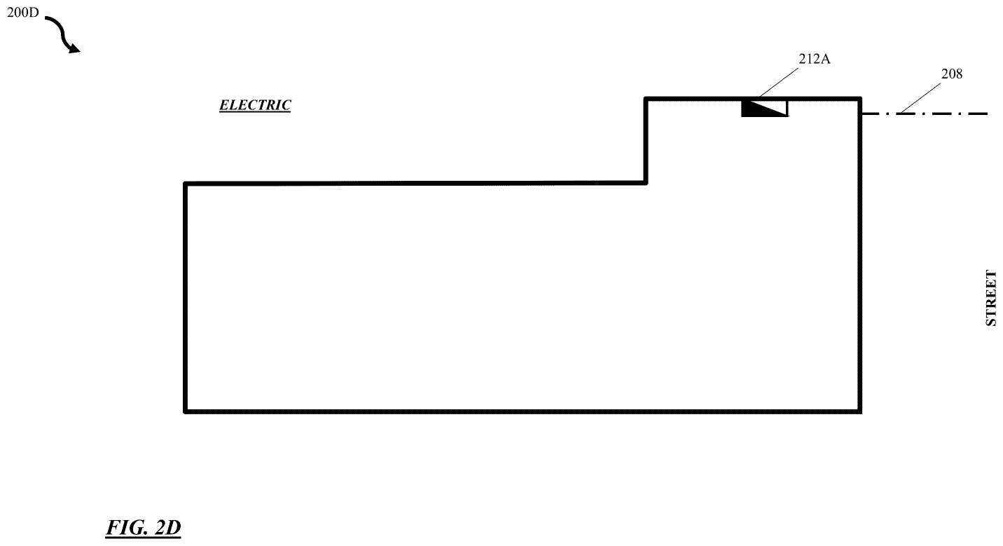

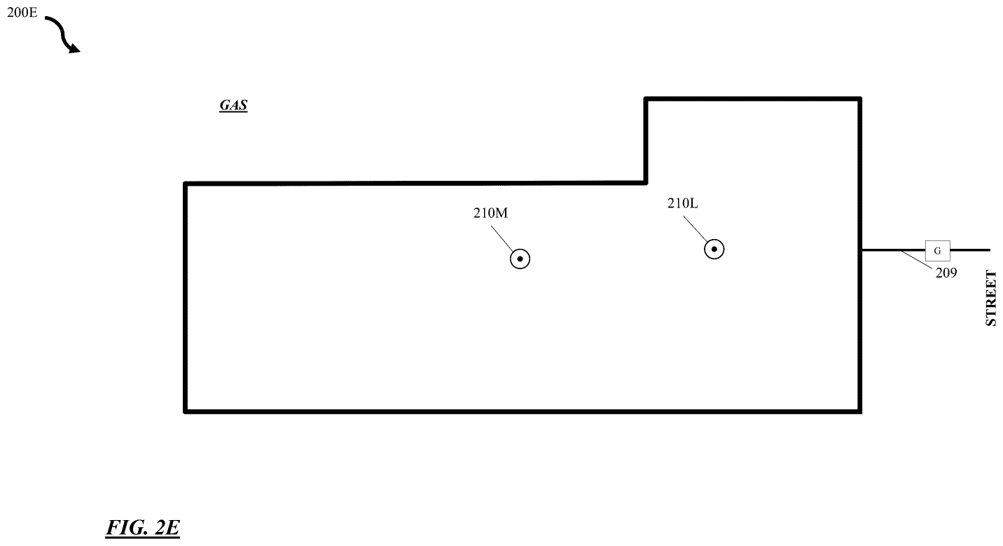

FIG. 2A is part of a simplified foundation plan 200A for a foundation, in particular indicating sewer outflows and external lines. Boundary 205 is a human-readable depiction of the foundation perimeter 107. Openings 210A-I represent planned openings in the foundation which can accommodate drainage or sewage. Sewage line 206 is a depiction of the sewage line exiting the foundation and travelling underground toward an adjacent street and public sewage utility line.

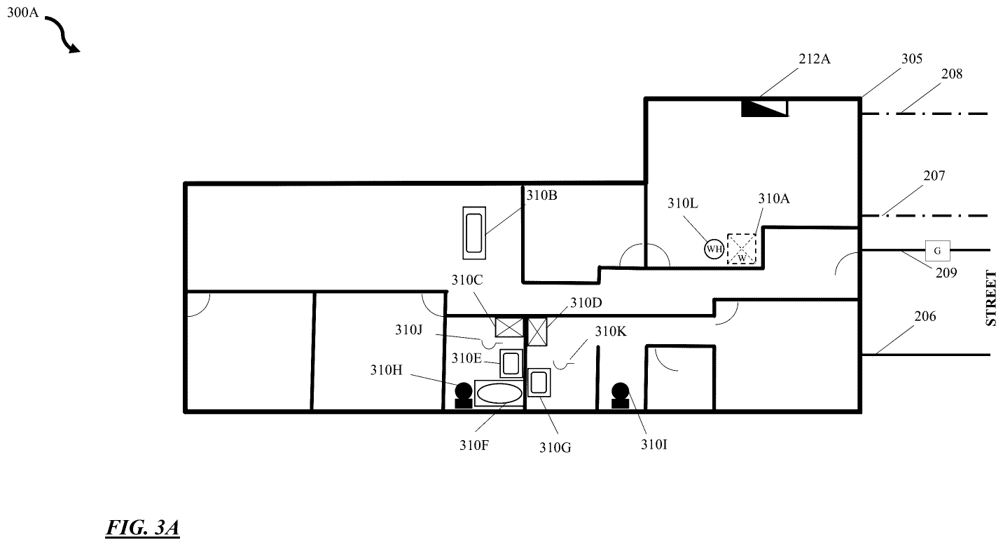

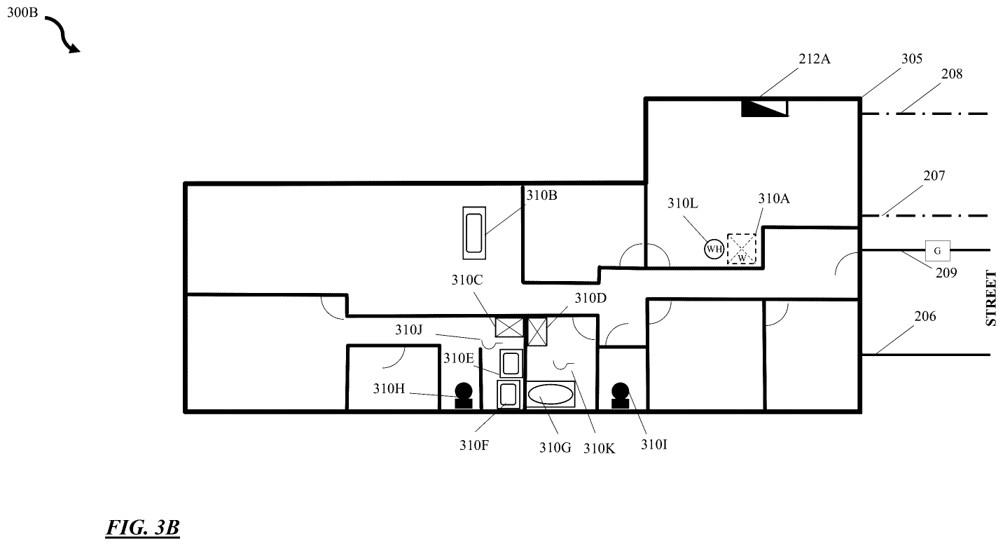

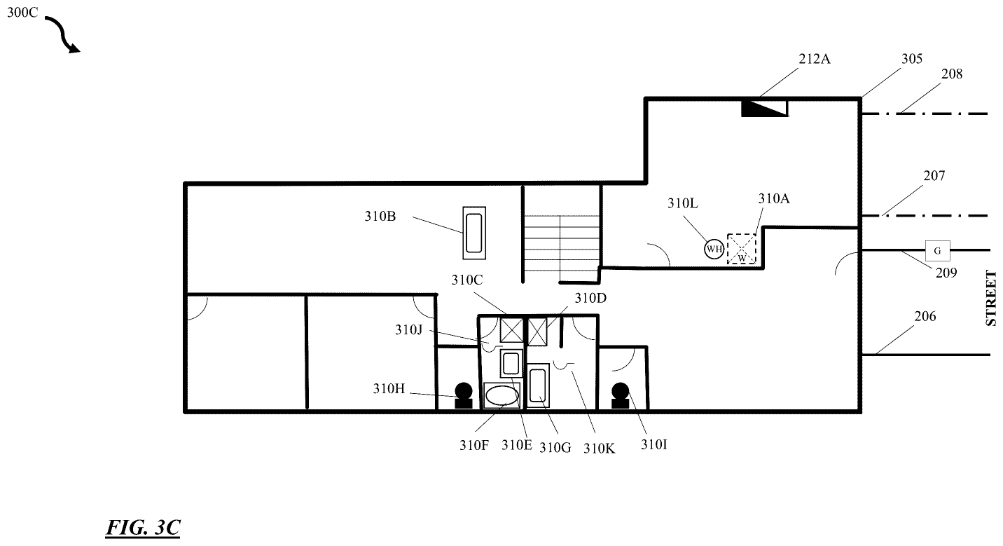

For the purposes of this disclosure, foundation plan 200A-E and structure plans 300A-C (see FIGS. 3A-C) may also be referred to when discussing or considering a final or prospective physical foundation based on foundation plan 200A-E, or a final or prospective physical constructed structure based on structure plans 300A-C.

Opening 210C-I are clustered together, as in many single family homes bathrooms and therefore sewage are clustered near or along a party wall between two bathrooms: this clustering also facilitates running lines, including sewage lines up to higher floors. These clustered areas are also often where any central vertical support beam which would require a load-bearing, immovable wall: by clustering foundation openings and support beams along a central load-bearing wall, maximum design flexibility is provided throughout the remainder of the structure plan 300A-C. However, clustering is not required, and clustering elsewhere within the boundary 205 or forming multiple sub-clusters is contemplated. Openings 210A and 210B are isolated, and may represent specialized rooms, such as kitchens, laundries, pools, water heaters, or other elements which are not necessarily desirable to locate near bathrooms.

FIG. 2B is part of the simplified foundation plan 200B of a foundation, in particular indicating cold water inflows and external lines. Openings 210A-I, L represent planned openings in the foundation which can accommodate cold water lines. Cold water line 207 is a depiction of the water line entering the foundation underground from an adjacent street and public water utility line.

FIG. 2C is part of the simplified foundation plan 200C of a foundation, in particular indicating hot water inflows and outflows. Openings 210A-G, L represent planned openings in the foundation which can accommodate hot water lines. In general, a hot water heater will be placed at a planned opening which has both access to a hot water opening 210 210A-G, L and a cold water opening 210A-G, L.

FIG. 2D is part of the simplified foundation plan 200D of a foundation, in particular indicating electrical panels and external lines. Electrical panel 212A represents the location of the electrical box for the house. Electrical line 208 is a depiction of the electrical line entering the foundation underground from an adjacent street and public energy utility line. In this example, electrical lines are intended be run through the walls of the ultimate structure, so no openings will accommodate electrical lines other than an opening at the electrical pane 212A.

FIG. 2E is part of the simplified foundation plan 200E of a foundation, in particular indicating gas outflows and external lines. Openings 210L,M represent planned openings in the foundation which can accommodate gas lines. Gas line 209 is a depiction of the gas line entering the foundation underground from an adjacent street and public gas utility line. In this example, openings 210L,M are intended to accommodate either a gas stove or a water heater—a water heater would also require nearby openings 210L for cold water and hot water.

FIG. 3A is a first structural plan 300A for a first structure affixable to the foundation of the foundation plan 200A-E. The first structural plan 300A must conform to the entire foundation plan 200A-E. The structural boundary 305 is generally congruent to the foundation boundary 205. The openings for the lines 206-209 in the first structural plan 300A overlap with the openings 206-209 in the foundation plan 200A-E. Fixtures 310A-L conform to the capabilities of their related openings 210A-L. The washing machine fixture 310A, sink fixtures 310B,E,G, shower fixtures 310C-D, and tub fixture 310F require drainage, cold water, and hot water, conforming with foundation plans 200A-C. These shared requirements indicate that, from the perspective of the foundation plans 200A-E, any of these fixtures 310A-G are interchangeable within structure input files 115A-D. Toilets 310H-I require cold water and drainage, and the hot water heater 310L requires cold water, hot water (to outflow), and gas connections. Fixture traps 310J-K only require a sewer connection, and are drains in the bathroom floor.

Rooms are designed around appropriate fixtures: e.g., full bathrooms have at least three sewer, three cold water, and two hot water openings. Rooms which do not require any openings 310A-L are fitted into the remaining space.

Based on the permissible fixture 310A-L locations, the structural plan 300A has constructed a 3-bedroom structure with a den, garage, street-facing master bedroom with a walk-in closet and an ensuite bathroom with a toilet privacy wall, and an additional full bathroom.

FIG. 3B is a second structural plan 300B for a second structure affixable to the foundation of the foundation plan 200A-E. This second plan 300B also conforms to the entire foundation plan 200A-E. From a fixture 310A-L perspective, the tub fixture 310F is replaced with a sink fixture 310F, and the sink fixture 310G is replaced with a tub fixture 310G. The structural plan 300A has constructed a 3-bedroom structure with a den, garage, rear-facing master bedroom with a walk-in closet and an ensuite bathroom with a toilet privacy wall, and half bathroom, and a private toilet.

FIG. 3C is a third structural plan for a third structure affixable to the foundation of the foundation plan 200A-E. This third plan 300C also conforms to the entire foundation plan 200A-E. From a fixture 310A-L perspective, the tub fixture 310G is rotated. The structural plan 300C has constructed a 2-bedroom structure with a stairs to an upper floor, garage, two half bathrooms, and two private toilets.

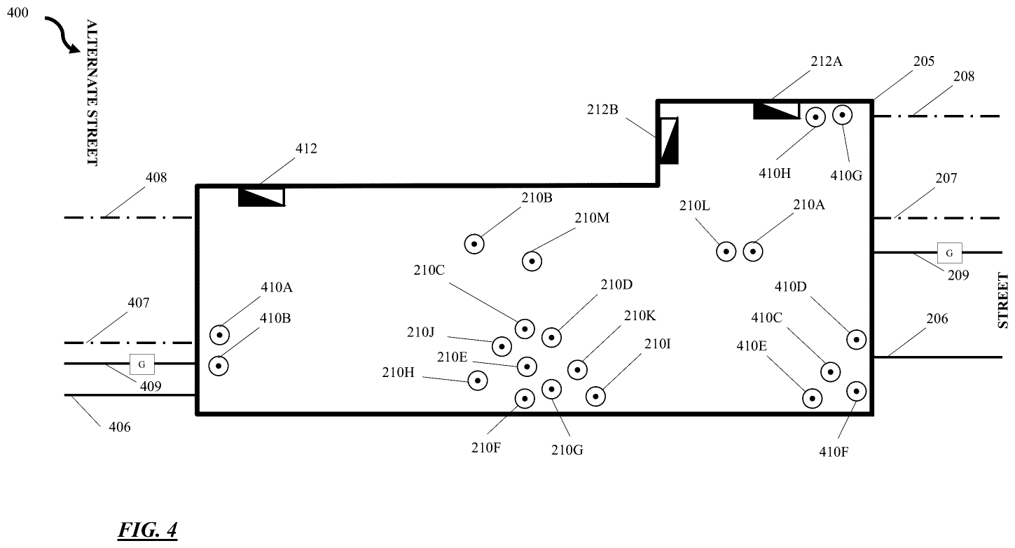

FIG. 4 depicts a foundation plan 400 for a foundation, in particular indicating an alternate set of utility outflows 406-409 and openings 410A-H. An alternate set of utility outflows 406-409 and openings 410A-H may be useful if it is unclear at the time of foundation planning which direction utilities will approach from, and where fixtures will be installed. Openings 410A-H may be partially or fully interconnected with openings 210A-M, or they may be entirely separately networked. One set of openings 210A-M 410A-H may be filled in, for example with expanding foam, or capped, in the event that that particular set of openings 210A-M is not used by the structure affixed to the foundation. Structure input files 115A-D can conform to this foundation plan if the structure opening points 120A-M overlap the appropriate openings 210A-M, or the appropriate openings 410A-H, or a combination thereof if those openings 210A-M 410A-H are partially or completely interconnected. Further, it is possible that, for example, water, gas, and electric use the lines 207-209, while sewage uses line 406 running to a septic tank in the back of the parcel. In such a case cold water, gas, and electric would need to utilize openings 210A-M, drainage would need to utilize openings 410A-H, and hot water would need to utilize openings 210A-M or openings 410A-H, unless one or more opening groups 210A-M 410A-H are partially or fully interconnected.

Therefore, FIGS. 1-4 depict a building foundation 200A-E including a foundation perimeter 205 and one or more foundation opening points 210A-M, the one or more foundation opening points 210A-M defined within or upon the foundation perimeter 205. The building foundation 200A-E is configured to allow the affixment of an initial structure 300A including one or more initial fixtures 310A-L. The one or more foundation opening points 210A-M are configured to align with one or more initial appliances affixed within the initial structure. The building foundation 200A-E is configured to allow the affixment of an alternative structure 300B-C including one or more alternative fixtures. The one or more foundation opening points 210A-M are configured to align with one or more alternative appliances affixed within the alternative structure 300B-C.

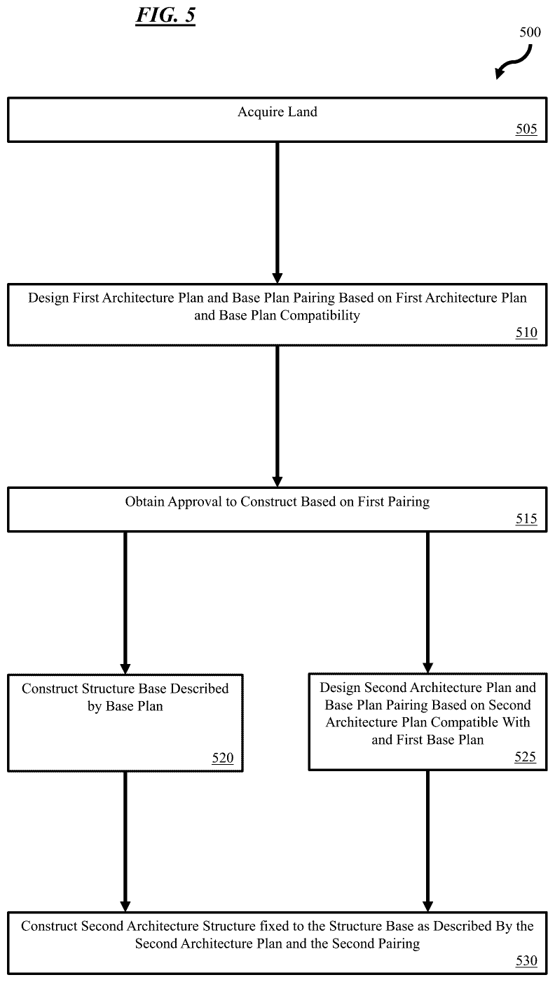

FIG. 5 is a flowchart depicting the dynamic structure plan foundation plan protocol 500. This protocol 500 describes using the plan alignment module 100 to facilitate improved dynamic and variable structure construction upon predetermined and approved foundations.

In block 505, a land developer acquires land. The land developer may also subdivide that land into parcels, and plan community features and utilities to service individual parcels on the land.

In block 510, on the land or a given parcel, the land developer designs a first architecture plan and base plan pairing (e.g., the initial pairing 140A) based on the first architecture plan (e.g., the initial structure input file 115D) and the base plan (e.g., foundation input file 105), which are compatible and conform to one another.

In block 515, the land developer obtains approval from the regulating authority to construct an initial structure defined by the first architecture plan upon a structure base defined by the base plan on the land or the given parcel.

In block 520, the land developer constructs a structure base as defined by the base plan on the land or the given parcel.

In block 525, which can occur concurrently with block 520, the land developer can utilize the plan alignment module 100 to design or select a second architecture plan and base plan pairing (e.g., the valid pairing 140B) based on the second architecture plan (e.g., structure input file 115A) and the base plan.

Once the structure base is constructed, and the land developer has designed or selected a second architecture plan and base plan pairing in block 530 the land developer constructs a structure based on the second architecture plan upon the structure base.

Management of the dynamic structure plan foundation plan protocol 500 can be facilitated by an automated building construction project management system as described in U.S. patent application Ser. No. 17/430,836, entitled “AUTOMATED BUILDING CONSTRUCTION PROJECT MANAGEMENT SYSTEM”, which is incorporated herein by reference in its entirety.

Therefore, FIG. 5 depicts a method including constructing a constructed foundation 200A-E in accordance with an initial architectural plan 140A on a plot of land in block 520. The method includes selecting an alternative architectural plan 140B from a plurality of alternative architectural plans 140A-B, each alternative architectural plan 140B of the plurality of alternative architectural plans 140A-B compatible for construction upon the constructed foundation 105 in block 525.

In some embodiments of the method, the constructed foundation 200A-E includes predetermined drainage points 210A-K (see FIG. 2A) configured to accommodate an initial plumbing configuration 310A-K of the initial architecture plan 300A and one or more alternative plumbing configurations 310A-K of one or more alternative architecture plans 300B-C of the plurality of alternative architectural plans 300A-C.

In a subset of those embodiments of the method, an initial boundary 305 of the initial architecture plan 300A is congruent with an alternative boundary 305 of the alternative architectural plan 300B. The initial plumbing configuration 310A-K (see FIG. 3A) aligns with the alternative plumbing configuration 310A-K (see FIG. 3B).

In some embodiments of the method, the method further includes selecting the initial architectural plan based on suitability for the plot of land in block 510. The method includes obtaining regulatory approval for the constructed foundation on the basis of the initial architectural plan in block 515. The method includes constructing an alternative residential structure according to the alternative architectural plan, upon the constructed foundation in block 530.

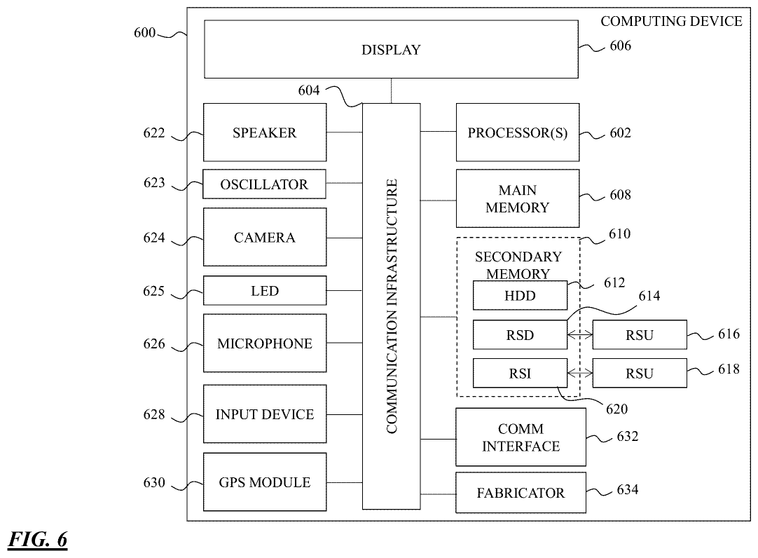

FIG. 6 is a block diagram of one example of an architecture of a computing device 600 that may be used in a system to implement a protocol, such as protocol 500, in accordance with some embodiments. Computing device 600 may be a cellular phone, a tablet, a desktop computer, a laptop computer, a server, a distributed computing environment, or any other suitable computing device as will be understood by one of ordinary skill in the art. As shown in FIG. 6, computing device 600 may include one or more processors, such as processor(s) 602. Processor(s) 602 may be any central processing unit (“CPU”), microprocessor, micro-controller, or computational device or circuit for executing instructions. Processor(s) 602 may be connected to a communication infrastructure 604 (e.g., a communications bus, crossover bar, or network). Various software embodiments are described in terms of this exemplary computing device 600. After reading this description, it will be apparent to one of ordinary skill in the art how to implement one or more disclosed methods using a mobile computing device 600 that may include other architectures and/or components. It should be understood that a computing device 600 implementing one or more of the disclosed methods may include some, all, or additional functional components as those of the computing device 600 illustrated in FIG. 6.

Computing device 600 may include a display 606 that displays graphics, video, text, and other data received from the communication infrastructure 604 (or from a frame buffer not shown) to a user. Examples of such displays 606 include, but are not limited to, LCD screens, LED display, OLED display, touch screen (e.g., capacitive, resistive optical imaging, infrared), and a plasma display, to name a few possible displays. Computing device 600 also may include a main memory 608, such as a random access (“RAM”) memory, and may also include a secondary memory 610. Secondary memory 610 may include a more persistent memory such as, for example, a hard disk drive (“HDD”) 612 and/or removable storage drive (“RSD”) 614, representing a magnetic tape drive, an optical disk drive, solid-state drive (“SDD”), or the like. In some embodiments, removable storage drive 614 may read from and/or writes to a removable storage unit (“RSU”) 616 in a manner that is understood by one of ordinary skill in the art. Removable storage unit 616 may represent a magnetic tape, optical disk, or the like, which may be read by and written to by removable storage drive 614. As will be understood by one of ordinary skill in the art, the removable storage unit 616 may include a tangible and non-transient machine-readable storage medium having stored therein computer software and/or data.

In some embodiments, secondary memory 610 may include other devices for allowing computer programs or other instructions to be loaded into computing device 600. Such devices may include, for example, a removable storage unit (“RSU”) 618 and a corresponding interface (“RSI”) 620. Examples of such units 618 and interfaces 620 may include a removable memory chip (such as an erasable programmable read only memory (“EPROM”)), programmable read only memory (“PROM”)), secure digital (“SD”) card and associated socket, and other removable storage units 618 and interfaces 620, which allow software and data to be transferred from the removable storage unit 618 to computing device 600.

Computing device 600 may also include a speaker 622, an oscillator 623, a camera (or other image capture device or sensor) 624, a light emitting diode (“LED”) 625, a microphone 626, an input device 628, and a global positioning system (“GPS”) module 630. Examples of input device 628 include, but are not limited to, a keyboard, buttons, a trackball, or any other interface or device through which a user may input data. In some embodiments, input device 628 and display 606 are integrated into the same component or device. For example, display 606 and input device 628 may be touchscreen through which a user uses a finger, pen, and/or stylus to input data into computing device 600.

Computing device 600 also may include one or more communication interfaces 632, which allows software and data to be transferred between computing device 600 and external devices that may be locally or remotely connected to computing device 600. Examples of the one or more communication interfaces 632 may include, but are not limited to, a modem, a network interface (such as an Ethernet card or wireless card), a communications port, a Personal Computer Memory Card International Association (“PCMCIA”) slot and card, one or more Personal Component Interconnect (“PCI”) Express slot and cards, or any combination thereof. The one or more communication interfaces 632 may also include a wireless interface configured for short-range communication, such as near field communication (“NFC”), Bluetooth, or other interface for communication via another wireless communication protocol.

Software and data transferred via the one or more communications interfaces 632 may be in the form of signals, which may be electronic, electromagnetic, optical, or other signals capable of being received by communications interfaces 632. These signals may be provided to communications interface 632 via a communications path or channel. The channel may be implemented using wire or cable, fiber optics, a telephone line, a cellular link, a radio frequency (“RF”) link, or other communication channels. The terms “non-transient computer program medium” and “non-transient computer readable medium” refer to media such as removable storage units 616, 618, or a hard disk installed in hard disk drive 612. These computer program products provide software to computing device 600. Computer programs (also referred to as “computer control logic”) may be stored in main memory 608 and/or secondary memory 610. Computer programs may also be received via the one or more communications interfaces 632. Such computer programs, when executed by a processor(s) 602, enable the computing device 600 to perform the methods discussed herein.

In some embodiments, where the method is partially or entirely implemented using software, the software may be stored in a computer program product as firmware and/or loaded into computing device 600 using removable storage drive 614, hard drive 612, and/or communications interface 632. The software, when executed by processor(s) 602, may cause the processor(s) 602 to perform the functions of the methods described herein. In some embodiments, the method may be implemented primarily in hardware using, for example, hardware components such as application specific integrated circuits (“ASICs”). Implementation of the hardware state machine so as to perform the functions described herein will be understood by persons skilled in the art. In some embodiments, the methods may be implemented using a combination of both hardware and software.

In some embodiments, the display 106 may be used as a light source and/or to display a reference pattern. A front-facing camera 624 of the computing device 600, i.e., the camera that is oriented to point in the same direction as the display 606, may be used as the image capture device. One of ordinary skill in the art will understand that other configurations are possible.

In some embodiments, the display 106 may show a land developer or customer one or more structure input files 115A-D representing a valid pairing 140A-B. a preferred structure input file may be selected using the input device. In some embodiments, the valid pairings 140A-B conform to regulations 152A-M, and are then ranked by the plan alignment module 100 based on preferential criteria e.g., number of bedrooms, number of full baths, ensuite baths, jack-and-jill baths, open concept kitchen and dining, windows in a den, walk-in closets, bedrooms only on higher floors, bedrooms preferably on higher floors, etc.

In some embodiments, computing device 600 may include a fabricator 634. Fabricator 634 can receive instructions in the form of a design plan, vectors, or points in a two- or three-dimensional grid, and fabricate objects conforming to those instructions. Some examples of fabricator 634 implementations can include 3D printers such as concrete 3D printers, precast fabricators, on-site fabricators, assembly line fabricators, automated pourers including automated concrete pourers, automated excavators, automated boring equipment, automated trenching equipment, and any other automated construction or site preparation equipment or solutions.

Therefore, FIGS. 1-4 and 6 depict an embodiment of a system 600 including a processor 602, an input device 628, 632 coupled to the processor 602, an output device 606, 632, 634 coupled to the processor 602, a memory 608, 610 coupled to the processor 602, and programming 100 in the memory 608, 610, wherein execution of the programming 100 by the processor 602 configures the system 600 to perform the following functions. The system 600 receives at the input device 628, 632 a foundation input file 105. The foundation input file 105 includes a foundation boundary vector space comprising one or more foundation boundary vectors 108A-F, the one or more foundation boundary vectors 108A-F forming a foundation perimeter 107. The foundation input file 105 also includes one or more foundation opening points 110A-M, the one or more foundation opening points 110A-M defined within or upon the foundation perimeter 107. The system 600 receives an initial structure input file 115D. The initial structure input file 115D includes an initial structure boundary vector space comprising one or more initial structure boundary vectors 118A-F, the one or more initial structure boundary vectors 118A-F forming an initial structure perimeter 117. The initial structure input file 115D also includes one or more initial structure opening points 120A-M, the one or more initial structure opening points 120A-M defined within or upon the initial structure perimeter 117. The system 600 determines an initial perimeter congruency value 130D between the foundation perimeter 107 and the initial structure perimeter 117. The system 600 determines an initial opening overlap value 132D where each initial structure opening point 120A-M overlaps an initial respective foundation opening point 110A-M of the foundation opening points 110A-M. The system 600 receives a plurality of alternative structure input files 115A-C. Each alternative structure input file 115A-C of the alternative structure input files 115A-C includes an alternative structure boundary vector space comprising one or more alternative structure boundary vectors 118A-F, the one or more alternative structure boundary vectors 118A-F forming an initial structure perimeter 117. Each alternative structure input file 115A-C also includes one or more alternative structure opening points 120A-M, the one or more alternative structure opening points 120A-M defined within or upon the alternative structure perimeter 117. For a respective alternative structure input file, the system 600 determines an alternative perimeter congruency value 130A-C between the foundation perimeter 107 and a respective alternative structure perimeter 117 of the respective alternative structure input file 115A-C. The system 600 determines an alternative opening overlap value 132A-C where each alternative structure opening point 120A-M overlaps an alternative respective foundation opening point 110A-M of the foundation opening points 110A-M. The system 600 determines the alternative perimeter congruency value 130A-C is within a congruency tolerance range 134 of the initial perimeter congruency value 130D, and the alternative opening overlap value 132A-C is within an overlap tolerance range 136 of the initial opening overlap value 132D. The system 600 outputs a valid pairing 140B including the foundation input file 105 and the respective alternative structure input file 115A.

Alternatively, in some embodiments the perimeter congruency value 130D and the opening overlap value 132D is determined based solely on the foundation input file 105, as opposed to utilizing both the initial structure input file 115D and the foundation input file 105. This alternative may be used if the final purchaser is comfortable with a structure that is smaller or less congruent than the structure described within the initial structure input file 115D, which nevertheless fits within the foundation perimeter 107 and has openings which each align with a respective foundation opening point 110A-M.

In some embodiments, the one or more foundation opening points 110A-M correspond to drainage openings.

In some embodiments, one or more edge foundation opening points 110A-D of the one or more foundation opening points corresponds to an external line 206-209.

In a subset of those embodiments, each foundation opening point 110A-M of the one or more foundation opening points 110A-M is a particular edge foundation opening point 110A-D of the edge foundation opening points 110A-D, or is an internal foundation opening point 110E-M connected to a respective edge foundation opening point 110A-D of the edge foundation opening points 110A-D.

In a subset of those embodiments, a connection between a respective internal foundation opening point 110E-M and the respective edge foundation opening point 110A-D corresponds to a dedicated connection.

In a different or overlapping subset of those embodiments, a connection between a respective internal foundation opening point 110E-M and the respective edge foundation opening point corresponds 110A-D to a general raceway or sleeve.

In some embodiments, the one or more foundation opening points 110A-M include correspondences to drainage openings, cold water openings, hot water openings, gas line openings, electrical line openings, or a combination thereof.

In some embodiments, the system 100 further includes a regulatory database 150, and the respective alternative structure input file 115A conforms to each relevant regulation 152A-M in the regulatory database 150.

In some embodiments, the foundation input file 105 corresponds to a constructed foundation, and the respective alternative structure file 115A corresponds to a constructed structure.

In a subset of those embodiments, the foundation opening points 110A-Z includes one or more unused opening points 110N-Z and one or more used opening points 110A-M. A respective unused opening point 110N-Z corresponds to a physical opening in the constructed foundation configured to be closed. A respective used opening point 110A-M corresponds to a physical connection between a fixture and an external line 206-209 via the respective used opening point 110A-M.

In a different or overlapping subset of those embodiments, the constructed foundation is a slab or a basement, and the constructed structure in a housing unit.

In some embodiments, an initial structure opening point 120A of the initial structure input file 115D corresponds to a fixture of a first type (e.g., a shower), and an alternative structure opening point 120A of an alternative structure input file 115A corresponds to a fixture of a second type (e.g., a bathtub, or anything other than the shower or fixture of the first type.)

In some embodiments, execution of the programming 100 by the processor 602 further configures the system 600 to perform the following functions. The system 600 outputs a preliminary pairing 140A including the foundation input file 105 and the initial structure input file 115D. The system 600 receives selection input selecting or ranking one or more of the plurality of alternative structure input files 115A-C. The system 600 outputs a preferred pairing 140B including the foundation input file 105 and a preferred alternative structure input file 115A, the preferred structure input file 115A being a most preferred alternative structure input file 115A among the selection input associated with a preferred congruency value 130A within the congruency tolerance range 134 of the initial perimeter congruency value 130D, the preferred opening overlap value 132A within the overlap tolerance range 136 of the initial opening overlap value 132D.

In some embodiments, one or more alternative structure input files 115A-C of the plurality of alternative structure input files 115A-C are generated by a machine learning or artificial intelligence module trained on one or more sample pairings 140A of a sample foundation input file 105 and a sample initial structure input file 115D.

In some embodiments, the system 600 further includes automated concrete pourer 634, and execution of the programming 100 by the processor 602 further configures the system 600 to perform the following functions. The system 600, utilizing the automated concrete pourer 634, fabricates a constructed foundation based upon the one or more foundation boundary vectors 108A-F and the one or more foundation opening points 110A-M of the foundation input file 105.

Embodiments of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Exemplary embodiments of the subject matter described in this specification, such as, but not limited to protocol 100 can be implemented as one or more computer programs, i.e., one or more modules of computer program instructions encoded on a tangible non-transitory program carrier for execution by, or to control the operation of, a data processing apparatus (or a computer system). According to some embodiments, “function,” “functions,” “application,” “applications,” “instruction,” “instructions,” or “programming” are program(s) that execute functions defined in the programs. Various programming languages can be employed to create one or more of the applications, structured in a variety of manners, such as object-oriented programming languages (e.g., Objective-C, Java, or C++), procedural programming languages (e.g., C or assembly language), or firmware. In a specific example, a third-party application (e.g., an application developed using the ANDROID™ or IOS™ software development kit (SDK) by an entity other than the vendor of the particular platform) may be mobile software running on a mobile operating system such as IOS™, ANDROID™, WINDOWS® Phone, or another mobile operating system. In this example, the third-party application can invoke API calls provided by the operating system to facilitate functionality described herein.

Additionally, or alternatively, the program instructions can be encoded on an artificially generated propagated signal, such as a machine-generated electrical, optical, or electromagnetic signal that is generated to encode information for transmission to suitable receiver apparatus for execution by a data processing apparatus. The computer storage medium can be a machine-readable storage device, a machine-readable storage substrate, a random or serial access memory device, or a combination of one or more of them.

Hence, a machine-readable medium may take many forms of tangible storage medium. Non-volatile storage media include, for example, optical or magnetic disks, such as any of the storage devices in any computer(s) or the like, such as may be used to implement the client device, media gateway, transcoder, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

The terms “apparatus,” “device,” and “system” refer to data processing hardware and encompass all kinds of apparatus, devices, and machines for processing data, including, by way of example, a programmable processor such as a graphical processing unit (GPU) or central processing unit (CPU), a computer, or multiple processors or computers. The apparatus, device, or system can also be or further include special purpose logic circuitry, such as an FPGA (field programmable gate array) or an ASIC (application specific integrated circuit). The apparatus, device, or system can optionally include, in addition to hardware, code that creates an execution environment for computer programs, such as code that constitutes processor firmware, a protocol stack, a database management system, an operating system, or a combination of one or more of them.

A computer program, which may also be referred to or described as a program, software, a software application, a module, a software module, a script, or code, can be written in any form of programming language, including compiled or interpreted languages, or declarative or procedural languages, and it can be deployed in any form, including as a standalone program or as a module, component, subroutine, or other unit suitable for use in a computing environment. A computer program may, but need not, correspond to a file in a file system. A program can be stored in a portion of a file that holds other programs or data, such as one or more scripts stored in a markup language document, in a single file dedicated to the program in question, or in multiple coordinated files, such as files that store one or more modules, sub programs, or portions of code. A computer program can be deployed to be executed on one computer or on multiple computers that are located at one site or distributed across multiple sites and interconnected by a communication network.

The processes, protocols, and logic flows described in this specification can be performed by one or more programmable computers executing one or more computer programs to perform functions by operating on input data and generating output. The processes, protocols, and logic flows can also be performed by, and apparatus can also be implemented as, special purpose logic circuitry, such as an FPGA (field programmable gate array), an ASIC (application specific integrated circuit), one or more processors, or any other suitable logic.

Computers suitable for the execution of a computer program include, by way of example, general or special purpose microprocessors or both, or any other kind of central processing unit (e.g., processor 602). Generally, a CPU will receive instructions and data from a read only memory or a random-access memory or both. The essential elements of a computer are a central processing unit for performing or executing instructions and one or more memory devices for storing instructions and data (e.g., main memory 608). Generally, a computer will also include, or be operatively coupled to receive data from or transfer data to, or both, one or more mass storage devices for storing data, such as magnetic, magneto optical disks, or optical disks (e.g., secondary memory 610, 910). However, a computer need not have such devices. Moreover, a computer can be embedded in another device, such as a mobile telephone, a personal digital assistant (PDA), a mobile audio or video player, a game console, a Global Positioning System (GPS) receiver, or a portable storage device, such as a universal serial bus (USB) flash drive, to name just a few.

Computer readable media suitable for storing computer program instructions and data include all forms of non-volatile memory, media and memory devices, including by way of example semiconductor memory devices, such as EPROM, EEPROM, and flash memory devices; magnetic disks, such as internal hard disks or removable disks; magneto optical disks; and CD ROM and DVD-ROM disks. The processor and the memory can be supplemented by, or incorporated in, special purpose logic circuitry.

To provide for interaction with a user, embodiments of the subject matter described in this specification can be implemented on a computer having a display unit, such as a CRT (cathode ray tube) or LCD (liquid crystal display) monitor, for displaying information to the user and a keyboard and a pointing device, such as a mouse or a trackball, by which the user can provide input to the computer. Other kinds of devices can be used to provide for interaction with a user as well; for example, feedback provided to the user can be any form of sensory feedback, such as visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's device in response to requests received from the web browser.

Implementations of the subject matter described in this specification can be implemented in a computing system that includes a back end component, such as a data server, or that includes a middleware component, such as an application server, or that includes a front end component, such as a computer having a graphical user interface or a Web browser through which a user can interact with an implementation of the subject matter described in this specification, or any combination of one or more such back end, middleware, or front end components. The components of the system can be interconnected by any form or medium of digital data communication, such as a communication network. Examples of communication networks include a local area network (LAN) and a wide area network (WAN), such as the Internet.

The computing system can include clients and servers. A client and server are generally remote from each other and typically interact through a communication network. The relationship of client and server arises by virtue of computer programs running on the respective computers and having a client-server relationship to each other. In some implementations, a server transmits data, such as an HTML page, to a user device, such as for purposes of displaying data to and receiving user input from a user interacting with the user device, which acts as a client. Data generated at the user device, such as a result of the user interaction, can be received from the user device at the server.

While this specification includes many specifics, these should not be construed as limitations on the scope of the invention or of what may be claimed, but rather as descriptions of features specific to particular embodiments of the invention. Certain features that are described in this specification in the context of separate embodiments may also be implemented in combination in a single embodiment. Conversely, various features that are described in the context of a single embodiment may also be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems may generally be integrated together in a single software product or packaged into multiple software products.

Various embodiments have been described herein with reference to the accompanying drawings. It will, however, be evident that various modifications and changes may be made thereto, and additional embodiments may be implemented, without departing from the broader scope of the disclosed embodiments as set forth in the claims that follow.

Further, other embodiments will be apparent to those skilled in the art from consideration of the specification and practice of one or more embodiments of the present disclosure. It is intended, therefore, that this disclosure and the examples herein be considered as exemplary only, with a true scope and spirit of the disclosed embodiments being indicated by the following listing of exemplary claims.

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents. Notwithstanding, none of the claims are intended to embrace subject matter that fails to satisfy the requirement of Sections 101, 102, or 103 of the Patent Act, nor should they be interpreted in such a way. Any unintended embracement of such subject matter is hereby disclaimed.

Except as stated immediately above, nothing that has been stated or illustrated is intended or should be interpreted to cause a dedication of any component, element, block, step, feature, object, benefit, advantage, or equivalent to the public, regardless of whether it is or is not recited in the claims. It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” “includes,” “including,” or any other variation thereof, are intended to cover a non-exclusive inclusion, such that a process, method, article, or apparatus that comprises or includes a list of elements, blocks, or steps does not include only those elements, blocks, or steps but may include other elements, blocks, or steps not expressly listed or inherent to such process, method, article, or apparatus. An element preceded by “a” or “an” does not, without further constraints, preclude the existence of additional identical elements in the process, method, article, or apparatus that comprises the element unless the context clearly and unambiguously dictates otherwise.

Unless otherwise stated, any and all measurements, values, ratings, positions, magnitudes, sizes, and other specifications that are set forth in this specification, including in the claims that follow, are approximate, not exact. Such amounts are intended to have a reasonable range that is consistent with the functions to which they relate and with what is customary in the art to which they pertain. For example, unless expressly stated otherwise, a parameter value or the like may vary by as much as ±10% from the stated amount.

In addition, in the foregoing Detailed Description, it can be seen that various features are grouped together in various examples for the purpose of streamlining the disclosure. This method of disclosure is not to be interpreted as reflecting an intention that the claimed examples require more features than are expressly recited in each claim. Rather, as the following claims reflect, the subject matter to be protected lies in less than all features of any single disclosed example. Thus the following claims are hereby incorporated into the Detailed Description, with each claim standing on its own as a separately claimed subject matter.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present concepts.

What is claimed is:

1. A system comprising:
a processor;
an input device, coupled to the processor;
an output device, coupled to the processor;
a memory, coupled to the processor; and
programming in the memory, wherein execution of the programming by the processor configures the system to perform the following functions:
receive at the input device a foundation input file, the foundation input file including:
a foundation boundary vector space comprising one or more foundation boundary vectors, the one or more foundation boundary vectors forming a foundation perimeter, and
one or more foundation opening points, the one or more foundation opening points defined within or upon the foundation perimeter;
receive an initial structure input file, the initial structure input file including:
an initial structure boundary vector space comprising one or more initial structure boundary vectors, the one or more initial structure boundary vectors forming an initial structure perimeter, and
one or more initial structure opening points, the one or more initial structure opening points defined within or upon the initial structure perimeter;
determine an initial perimeter congruency value between the foundation perimeter and the initial structure perimeter;
determine an initial opening overlap value where each initial structure opening point overlaps an initial respective foundation opening point of the foundation opening points;
receive a plurality of alternative structure input files, each alternative structure input file of the alternative structure input files including:
an alternative structure boundary vector space comprising one or more alternative structure boundary vectors, the one or more alternative structure boundary vectors forming an alternative structure perimeter, and
one or more alternative structure opening points, the one or more alternative structure opening points defined within or upon the alternative structure perimeter;
for a respective alternative structure input file:
determine an alternative perimeter congruency value between the foundation perimeter and a respective alternative structure perimeter of the respective alternative structure input file;
determine an alternative opening overlap value where each alternative structure opening point overlaps an alternative respective foundation opening point of the foundation opening points;
determine the alternative perimeter congruency value is within a congruency tolerance range of the initial perimeter congruency value, and the alternative opening overlap value is within an overlap tolerance range of the initial opening overlap value;
output a valid pairing including the foundation input file and the respective alternative structure input file.

2. The system of claim 1, wherein the one or more foundation opening points correspond to drainage openings.

3. The system of claim 1, wherein one or more edge foundation opening points of the one or more foundation opening points corresponds to an external line.

4. The system of claim 3, wherein each foundation opening point of the one or more foundation opening points is a particular edge foundation opening point of the edge foundation opening points, or is an internal foundation opening point connected to a respective edge foundation opening point of the edge foundation opening points.

5. The system of claim 4, wherein a connection between a respective internal foundation opening point and the respective edge foundation opening point corresponds to a dedicated connection.

6. The system of claim 4, wherein a connection between a respective internal foundation opening point and the respective edge foundation opening point corresponds to a general raceway.

7. The system of claim 1, wherein the one or more foundation opening points include correspondences to:
i) drainage openings,
ii) cold water openings,
iii) hot water openings,
iv) gas line openings,
v) electrical line openings, or
vi) a combination thereof.

8. The system of claim 1, further comprising a regulatory database; and
wherein the respective alternative structure input file conforms to each relevant regulation in the regulatory database.

9. The system of claim 1, wherein the foundation input file corresponds to a constructed foundation, and the respective alternative structure file corresponds to a constructed structure.

10. The system of claim 9, wherein:
the foundation opening points includes one or more unused opening points and one or more used opening points;
a respective unused opening point corresponds to a physical opening in the constructed foundation configured to be closed; and
a respective used opening point corresponds to a physical connection between a fixture and an external line via the respective used opening point.

11. The system of claim 9, wherein the constructed foundation is a slab or a basement, and the constructed structure in a housing unit.

12. The system of claim 1, wherein an initial structure opening point corresponds to a fixture of a first type, and an alternative structure opening point corresponds to a fixture of a second type.

13. The system of claim 1, wherein execution of the programming by the processor further configures the system to perform the following functions:
output a preliminary pairing including the foundation input file and the initial structure input file;
receive selection input selecting or ranking one or more of the plurality of alternative structure input files;
output a preferred pairing including the foundation input file and a preferred alternative structure input file, the preferred structure input file being a most preferred alternative structure input file among the selection input associated with a preferred congruency value within the congruency tolerance range of the initial perimeter congruency value, the preferred opening overlap value within the overlap tolerance range of the initial opening overlap value.

14. The system of claim 1, wherein one or more alternative structure input files of the plurality of alternative structure input files are generated by a machine learning or artificial intelligence module trained on one or more sample pairings of a sample foundation input file and a sample initial structure input file.

15. The system of claim 1, further comprising:
an automated concrete pourer; and
wherein execution of the programming by the processor further configures the system to perform the following functions:
utilizing the automated concrete pourer, fabricate a constructed foundation based upon the one or more foundation boundary vectors and the one or more foundation opening points of the foundation input file.

16. A method, comprising:
constructing a constructed foundation in accordance with an initial architectural plan on a plot of land;
selecting an alternative architectural plan from a plurality of alternative architectural plans, each alternative architectural plan of the plurality of alternative architectural plans compatible for construction upon the constructed foundation.

17. The method of claim 16, wherein the constructed foundation includes predetermined drainage points configured to accommodate an initial plumbing configuration of the initial architecture plan and one or more alternative plumbing configurations of one or more alternative architecture plans of the plurality of alternative architectural plans.

18. The method of claim 17, wherein:
an initial boundary of the initial architecture plan is congruent with an alternative boundary of the alternative architectural plan; and
the initial plumbing configuration aligns with the alternative plumbing configuration.

19. The method of claim 16, further comprising:
selecting the initial architectural plan based on suitability for the plot of land;
obtaining regulatory approval for the constructed foundation on the basis of the initial architectural plan;
constructing an alternative residential structure according to the alternative architectural plan, upon the constructed foundation.

20. A building foundation, comprising:
a foundation perimeter; and
one or more foundation opening points, the one or more foundation opening points defined within or upon the foundation perimeter; and
wherein:
the building foundation is configured to allow the affixment of an initial structure including one or more initial fixtures;
the one or more foundation opening points are configured to align with one or more initial appliances affixed within the initial structure;
the building foundation is configured to allow the affixment of an alternative structure including one or more alternative fixtures; and
the one or more foundation opening points are configured to align with one or more alternative appliances affixed within the alternative structure.
